(19) United States
(12) Patent Application Publication
(10) Pub. No.: US 2019/0116658 A1
(43) Pub. Date: Apr. 18, 2019

(54) FLEXIBLE ELECTRODE LAMINATE AND METHOD FOR MANUFACTURING THE SAME

(71) Applicant: POSTECH ACADEMY-INDUSTRY FOUNDATION, Pohang-si (KR)

(72) Inventors: Unyong JEONG, Pohang-si (KR); Jun Hyuk Song, Seoul (KR)

(21) Appl. No.: 15/944,845

(22) Filed: Apr. 4, 2018

(30) Foreign Application Priority Data
Oct. 13, 2017 (KR) 10-2017-0133044

(51) Int. Cl. H05K 1/02; C09J 125/08; C09J 131/04; H05K 3/20; H05K 3/46

(52) U.S. Cl. CPC H05K 1/028; C09J 125/08; H05K 3/4614; H05K 3/20; C09J 131/04

(57) ABSTRACT

The present invention relates to a method of manufacturing an electrode laminate and to a flexible and stretchable electrode laminate manufactured using the same. The method includes (a) printing a conductive print ink including a metal precursor, an organic solvent, and a polymer on a flexible substrate to thus form a conductive print ink pattern impregnated into the flexible substrate, and (b) reducing the conductive print ink pattern to thus manufacture the electrode laminate. The present invention provides a method of manufacturing a flexible and stretchable electrode laminate which is simpler and which consumes less time than a conventional manufacturing method.

### BACKGROUND OF THE INVENTION

### 1. Field of the Invention

The present invention relates to a flexible electrode laminate and a method of manufacturing the same. More particularly, the present invention relates to an electrode laminate which enables increased freedom of patterning and which secures reproducibility and reliability of an electrode element by directly applying a metal precursor and an organic solvent used as an ink to nozzle and inkjet printing, and a method of manufacturing the same.

### 2. Description of the Related Art

In recent years, research on flexible and stretchable electrodes has received great interest due to the growing interest in electronic skin, deformable electronic devices, and wearable devices. Flexible/extensible electrodes require various conditions such as low creep characteristics, abrasion resistance, peel resistance, low cost, and easy processing methods. However, the two most important requirements are high electrical conductivity like metal, and high flexibility and extensibility to withstand various types of deformations with various intensities.

Meanwhile, there have been many studies to manufacture flexible and stretchable electrodes to date, but in these studies, it has been difficult to use complex or time-consuming methods such as vapor deposition or to perform patterning. Therefore, there have been attempts to manufacture flexible and stretchable electrodes using a printing method, but such attempts are fraught with many difficulties. That is, the manufacture of the flexible and stretchable electrodes using the printing method is mainly focused on a method of manufacturing an ink using conductive metal nanoparticles and printing the ink. However, such inks have a drawback in that a complicated and time-consuming method such as screen printing must be used due to the very high viscosity.

Accordingly, there is a need for a method of manufacturing a flexible and stretchable electrode which is simpler and which consumes less time than a conventional manufacturing method.

### SUMMARY OF THE INVENTION

Accordingly, the present invention has been made keeping in mind the above problems occurring in the related art, and an object of the present invention is to provide a method of manufacturing a flexible and/or stretchable electrode laminate which is simpler and consumes less time than a conventional manufacturing method.

Another object of the present invention is to provide an electrode laminate which is manufactured using the above-described manufacturing method and which is applicable to various flexible and stretchable electronic elements.

Yet another object of the present invention is to provide an electrochemiluminescence element including the above-described electrode laminate.

In order to accomplish the above objects, an aspect of the present invention provides an electrode laminate which includes a flexible substrate including a recess unit, and an electrode formed in the recess unit and including metal nanoparticles.

In the electrode laminate according to an embodiment of the present invention, the recess unit may be formed in a pattern on one side of the substrate.

Further, the electrode may further include a polymer.

Further, the polymer may include a material that is identical with the material of the flexible substrate.

Further, the recess unit may be formed by impregnating the substrate with a print solution including the metal nanoparticles, from the surface of the substrate to the inside the substrate.

Further, the substrate may include one or more selected from the group consisting of an SBS block copolymer (polystyrene-block-polybutadiene-block-polystyrene copolymer), an SEBS block copolymer (polystyrene-block-poly(ethylene-butylene)-block-polystyrene copolymer), an SIS block copolymer (polystyrene-block-polyisoprene-block-polystyrene copolymer), an SB block copolymer (polystyrene-block-polybutadiene copolymer), an SMMA block copolymer (polystyrene-block-poly(methyl methacrylate) copolymer), an SEO block copolymer (polystyrene-block-poly(ethylene oxide) copolymer), an SVP block copolymer (polystyrene-block-poly(vinyl pyridine) copolymer), and polyurethane.

Further, the metal nanoparticles may include one or more metals selected from the group consisting of Ag, Au, Pt, Al, Cu, Pd, Li, and Zn.

Further, the metal nanoparticles may include silver.

Another aspect of the present invention provides an electrochemiluminescence element which includes a lower electrode including the above-described electrode laminate, an electrochemiluminescence gel formed on the lower electrode, and an upper electrode formed on the electrochemiluminescence gel.

Yet another aspect of the present invention provides a method of manufacturing an electrode laminate, the method including (a) printing a conductive print ink including a metal precursor, an organic solvent, and a block copolymer on a flexible substrate to thus form a conductive print ink pattern impregnated in the flexible substrate, and (b) reducing the conductive print ink pattern to thus manufacture the electrode laminate.

In the method of manufacturing the electrode laminate according to an embodiment of the present invention, the printing the conductive print ink may be performed using a nozzle or inkjet printer.

Further, the conductive print ink printed on the substrate may swell and impregnate the substrate, from the surface of the substrate to the inside thereof.

Further, the printing the conductive print ink may be performed multiple times over the same region of the substrate.

Further, the substrate may include one or more selected from the group consisting of an SBS block copolymer, an SEBS block copolymer, an SIS block copolymer, an SB block copolymer, an SMMA block copolymer, an SEO block copolymer, an SVP block copolymer, and polyurethane.

Further, metal ions of the metal precursor may include one or more metal ions selected from the group consisting of Ag, Au, Pt, Al, Cu, Pd, Li, and Zn.

Further, the metal precursor may include one or more selected from the group consisting of CF₃COOAg, AgNO₃, AgCl, HAuCl₄, CuCl₂, PtCl₂, PtCl₄, CF₃COO₂Pd, CF₃CO₂Li, and Zn(CF₃COO) ₂ .

Further, the organic solvent may include one or more selected from the group consisting of acetone, butanone, methanol, ethanol, and butanol.

Further, the polymer may include one or more selected from the group consisting of an SBS block copolymer, an SEBS block copolymer, an SIS block copolymer, an SB block copolymer, an SMMA block copolymer, an SEO block copolymer, an SVP block copolymer, and polyurethane.

Further, the reducing the conductive print ink pattern printed on the substrate may be performed by immersing the substrate that is subjected to printing in a reductant solution.

Further, the reductant may include one or more selected from the group consisting of hydrazine (N₂H₄), sodium borohydride (NaBH₄), formaldehyde (HCHO), and sodium hydroxide (NaOH).

A method of manufacturing an electrode laminate according to the present invention has a merit in that since a metal precursor and an organic solvent are used as an ink, direct application to nozzle and inkjet printing is feasible. Particularly, since a printer is used, patterning freedom can be greatly increased and the reproducibility and the reliability of an electrode element can be secured.

Further, according to the manufacturing method of the present invention, since the ink is swelled and infiltrated into the substrate to be printed therewith by simply printing and then reducing the ink without any special post-treatment, silver nanoparticles which will form a conducting path are generated on the surface and in the inside of the film. Therefore, the resistance of the electrode is not greatly increased, but is maintained even if mechanical stress is applied to the electrode.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a schematic view showing a procedure of a method of manufacturing an electrode laminate according to an embodiment of the present invention, and is a TEM (transmission electron microscope) image of the electrode laminate manufactured thereby;

FIG. 2 is an SEM (scanning electron microscope) image of a conductive line pattern printed on a substrate;

FIGS. 3A, 3B, 3C and 3D is a graph showing the electrical characteristics of the electrode laminate according to the present invention; and

FIG. 4A is a mimetic diagram of an electrochemiluminescence element including the electrode laminate according to the present invention, and FIG. 4B is a picture showing the actual embodiment of an electrochemiluminescence element through which electricity flows.

### DESCRIPTION OF THE PREFERRED EMBODIMENTS

Hereinafter, embodiments of the present invention will be described in detail with reference to the accompanying drawings so that those skilled in the art can easily carry out the present invention.

However, the following description does not limit the present invention to the specific embodiments, and descriptions of known related techniques, even if they are pertinent to the present invention, may be omitted insofar as they would make the gist of the present invention unclear.

The terminology used herein is for the purpose of describing specific embodiments only and is not intended to be limiting of the invention. Unless otherwise stated, the singular expression includes a plural expression. In this application, the terms “include” or “have” are used to designate the presence of features, numbers, steps, operations, components, or combinations thereof described in the specification, and should be understood as not excluding the presence or addition possibility of one or more different features, numbers, steps, operations, components, or combinations thereof.

Further, terms including ordinals such as “first”, “second”, etc. that may be used below may be used to describe various components, but these components are not to be limited by the terms. The terms are only used to distinguish one component from another. For example, a first component may be termed a second component, and, similarly, a second component may be termed a first component, without departing from the scope of the present invention.

Further, it will be understood that when a component is referred to as being “formed” or “layered” on another component, it can be formed or layered so as to be directly attached to the entire surface or one surface of the other component, or intervening components may be present therebetween.

Hereinafter, the present invention will be described in detail. However, it should be understood that this is presented as an embodiment, and the present invention is not limited thereto, but is only defined by the scope of the following claims.

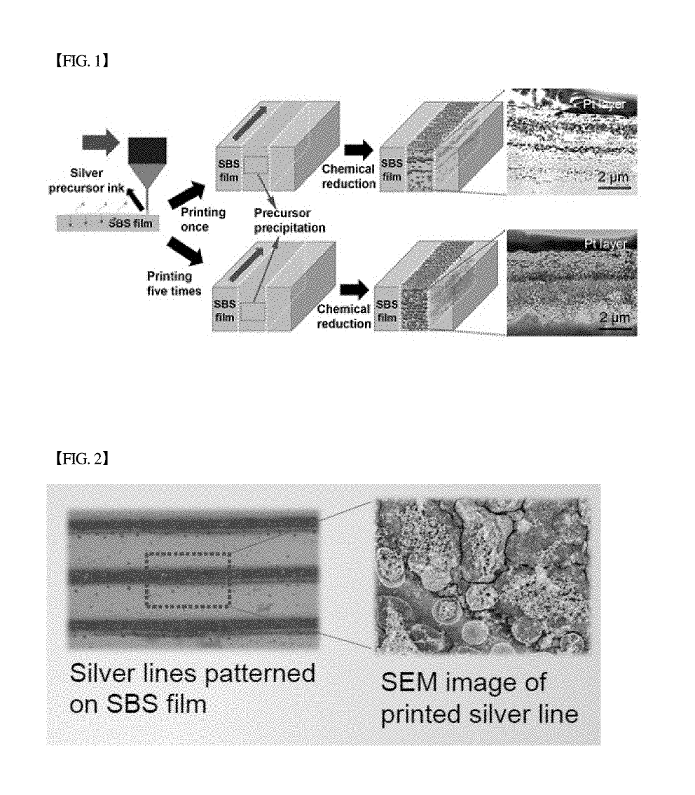

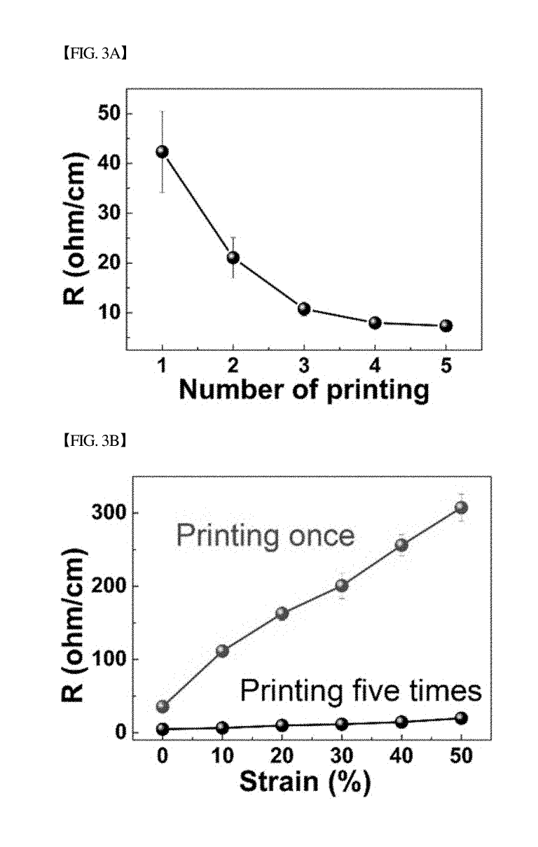

FIG. 1 is a view schematically showing a method of manufacturing an electrode laminate according to the present invention, and FIG. 2 is an SEM image of a conductive line pattern printed on a substrate.

Referring to FIGS. 1 and 2, the method of manufacturing the electrode laminate according to the present invention includes (a) printing a conductive print ink including a metal precursor, an organic solvent, and a block copolymer on a flexible substrate to thus form a conductive print ink pattern impregnated into the flexible substrate, and (b) reducing the conductive print ink pattern to thus manufacture the electrode laminate.

(1) Manufacture of Conductive Print Ink:

First, the metal precursor and a small amount of the block copolymer are dissolved in the organic solvent, thus manufacturing the conductive print ink.

In the present invention, the metal ion of the metal precursor may include one or more metal ions selected from the group consisting of Ag, Au, Pt, Al, Cu, Pd, Li, and Zn. Preferably, silver trifluoroacetate may be used as the metal precursor.

In the present invention, examples of the organic solvent may include one or more selected from the group consisting of acetone, butanone, methanol, ethanol, and butanol. Preferably, acetone or ethanol may be used. Silver trifluoroacetate, which is the metal precursor, exhibits very high solubility in solvents such as acetone and ethanol.

According to the present invention, it is preferable that a small amount of the polymer be included in the print ink. The function of the polymer will be described later in detail. In the present invention, examples of the polymer may include one or more selected from the group consisting of an SBS block copolymer, an SEBS block copolymer, an SIS block copolymer, an SB block copolymer, an SMMA block copolymer, an SEO block copolymer, an SVP block copolymer, and polyurethane. Preferably, an SBS block copolymer may be used.

(2) Provision of Flexible and Stretchable Substrate:

The present invention is directed to printing the conductive print ink that is manufactured as described above on a flexible and stretchable substrate.

In the present invention, examples of the flexible and stretchable substrate may include a substrate including one or more selected from the group consisting of an SBS block copolymer, an SEBS block copolymer, an SIS block copolymer, an SB block copolymer, an SMMA block copolymer, an SEO block copolymer, an SVP block copolymer, and polyurethane. Preferably, an SBS block copolymer film may be used.

(3) Printing Conductive Print Ink on Substrate:

According to the present invention, the conductive print ink pattern is formed on the substrate by printing the conductive print ink, manufactured as described above, on the substrate. According to the present invention, since the print ink swells and infiltrates into the substrate to be printed therewith, metal nanoparticles which will form a conducting path are generated on the surface and in the inside of the film when a reduction process is performed. Therefore, the resistance of the electrode is not greatly increased but is maintained even when mechanical stress is applied to the electrode. The phenomenon whereby the ink swells and infiltrates into the substrate is caused by a combination of (1) a coordination effect of the metal precursor (silver trifluoroacetate), the double bond of a block copolymer chain, and an aromatic ring, and (2) a solution diffusion effect.

Further, in the present invention, a step of printing the conductive print ink is performed using nozzle and inkjet printers. According to the present invention, since the metal precursor and the organic solvent are used as the print ink, there is a merit in that direct application to nozzle or inkjet printing is feasible. Particularly, since the printer is used, it is possible to greatly increase patterning freedom and to secure the reproducibility and the reliability of the electrode element.

In the present invention, when the ink is printed on the substrate, the printed ink quickly spreads in the lateral direction of the substrate. In order to prevent this, a small amount of the block copolymer, preferably an SBS block copolymer, may be added to a mixed solution of the metal precursor and the organic solvent, thus increasing the viscosity of the ink.

Further, according to the present invention, the print ink is printed on the substrate, and then the printing is performed multiple times in the same place, whereby the ink more effectively infiltrates into the substrate.

(4) Reduction of Printed Portion:

Subsequently, the substrate that is subjected to printing is immersed in a reductant solution, thus reducing the printed portion.

In the present invention, examples of a reductant may include one or more selected from the group consisting of hydrazine (N₂H₄), sodium borohydride (NaBH₄), formaldehyde (HCHO), and sodium hydroxide (NaOH).

As described above, the metal precursor is chemically reduced, thus being converted into metal nanoparticles, thereby manufacturing a flexible and stretchable electrode laminate having a structure (surface-embedded structure) of infiltration ranging from the surface of the substrate to the inside of the substrate.

The upper right picture of FIG. 1 is a TEM image of the cross-section of the electrode manufactured by printing one time, showing that silver nanoparticles are formed from the surface of the substrate to a depth of about 2 μm into the substrate. However, the silver nanoparticles are not completely connected with each other from the surface of the substrate to the inside of the substrate. Meanwhile, the lower right picture of FIG. 1 is a TEM image of the cross-section of the electrode manufactured by printing five times, showing that the silver nanoparticles are connected with each other from the surface of the substrate to the inside of the substrate.

FIG. 2 is an SEM image of a line-patterned electrode, clearly showing that the silver nanoparticles are distributed on the surface of the substrate.

The electrode laminate that is manufactured as described above may be applied to various electronic elements including wearable devices.

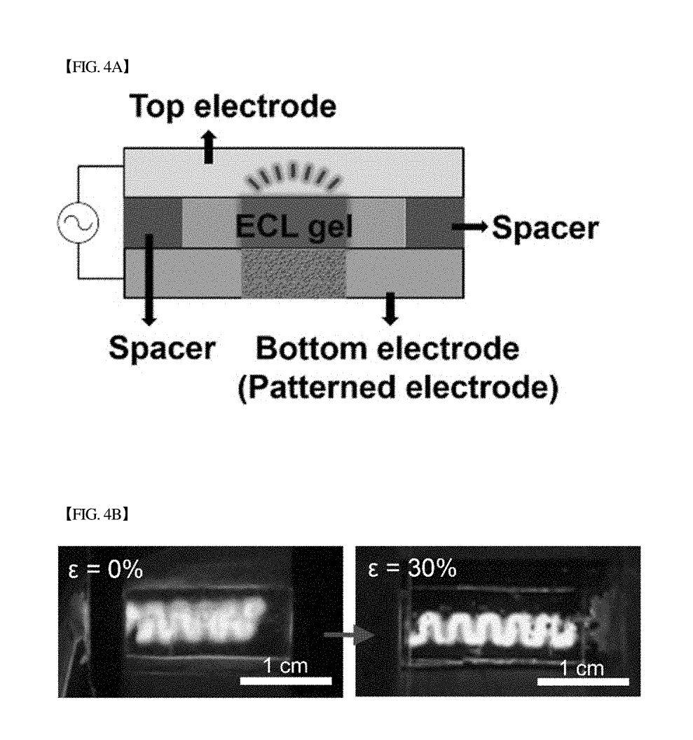

FIG. 4A is a mimetic diagram of an electrochemiluminescence element including the electrode laminate according to the present invention. Referring to FIG. 4A, the electrochemiluminescence element according to the present invention may include a lower electrode including the electrode laminate, an electrochemiluminescence gel formed on the lower electrode, and an upper electrode formed on the electrochemiluminescence gel.

Hereinafter, the present invention will be described in more detail with reference to examples. However, this is for illustrative purposes only, and thus the scope of the present invention is not limited thereto.

### EXAMPLE

### Example 1: Manufacture of Flexible and stretchable Electrode Laminate (Printing Five Times)

0.5 g of silver trifluoroacetate was dissolved in 0.5 g of acetone, 2 mg of SBS was added, and strong agitation was performed so as to obtain complete dissolution. The prepared silver precursor ink was sealed using Parafilm (Bemis) and stored in a refrigerator until use.

Subsequently, a silver precursor ink was printed in a line form on an SBS film having a thickness of 2 μm using a nozzle printer (Musashi, Image Master 350PC). When printing, a header having a diameter of 200 μm was used, and the speed of the printer header was maintained at 100 mm/s.

The above-described printing operation was performed on each substrate five times. Subsequently, the substrates that were subjected to printing were immersed in a diluted hydrazine hydrate solution for about 1 hour to thus reduce the silver precursor, thereby manufacturing a flexible and stretchable electrode laminate in which silver nanoparticles were connected with each other from the surface of the substrate to the inside of the substrate.

### Example 2: Manufacture of Flexible and Stretchable Electrode Laminate (Printing One Time)

The electrode laminate was manufactured using the same method as in Example 1, except that the printing operation was performed only once.

### Element Example 1: Manufacture of Electrochemiluminescence (ECL) Display

14 g of acetone, 2 g of poly(vinylidene fluoride-co-hexafluoropropylene), and 12 g of 1-ethyl-3-methylimidazolium bis(trifluoromethylsulfonyl)imide were mixed and then treated using ultrasonic waves, thus manufacturing an ECL gel.

Subsequently, spacers were placed on the electrode laminate manufactured as in Example 1, and the electrode therebetween was coated with the ECL gel. An ECL display as schematically shown in FIG. 4A was manufactured by placing flexible ITO on an ECL gel coating layer and using the resulting structure as an upper electrode. A function generator (KEYSIGHT, 33210A) was used to generate an AC voltage (Vpp=7 V, frequency of 50 Hz).

FIG. 4B is before and after pictures showing unilateral strain on the ECL display manufactured as described above (ε=30%). Referring to FIG. 4B, it can be seen that the light emission is improved in a strained state because the size of a light-emitting region is increased due to elongation.

### Test Example: Analysis of Electrical Characteristics of Electrode that is Subjected to Printing

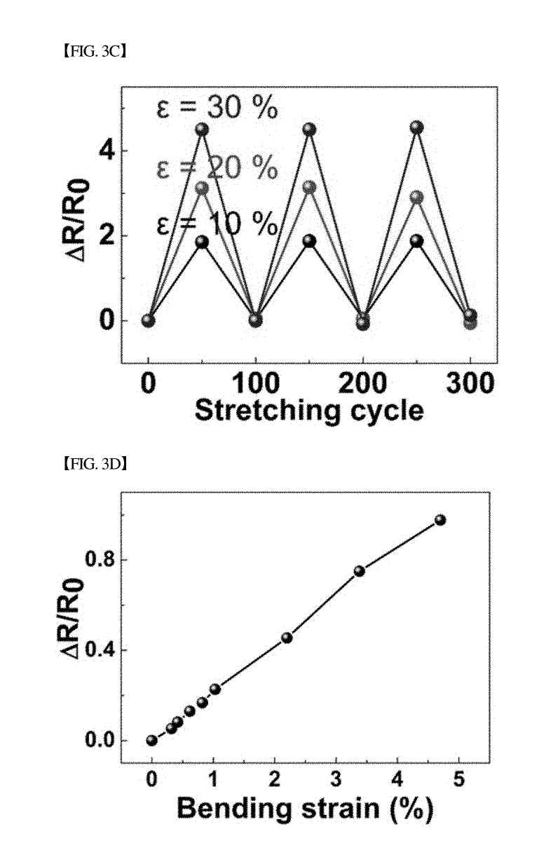

FIG. 3A shows a change in resistance depending on the number of times the line-patterned (line width of 200 μm) electrode is printed on an SBS film (having a thickness of 2 μm). Referring to FIG. 3A, the resistance was 42 Ω/cm when printing was performed one time, and was reduced to 22 Ω/cm when printing was performed two times and then gradually reduced to 6 Ω/cm, which was a saturation value, when printing was performed five times.

FIG. 3B shows the response of the electrode to unilateral strains until ε was 50%. The strain was applied in a direction that was parallel to a line direction. Referring to FIG. 3B, the electrode that was subjected to printing one time exhibited a sensitive response to external strain, and thus such an electrode may be used as a piezo-resistive strain sensor. Conversely, in the case of the electrode that was subjected to printing five times, there was almost no change in resistance in response to the strain until ε was 30%. Accordingly, this electrode may be used for a stretchable circuit.

FIG. 3C shows a relative resistance change over 300 stretching cycles at ε of 10%, 20%, and 30% for the electrode that was subjected to printing one time. Referring to FIG. 3C, the relative resistance change exhibits very high stability under mechanical deformation.

FIG. 3D shows a relative resistance change during a bending test in a small strain region (ε≤5%) in the case of the electrode that was subjected to printing one time. Referring to FIG. 3D, the electrode exhibits a linear response in an entire strain region including a very small strain region (ε≤1%), in which a typical stretchable strain sensor does not have a high sensing resolution. This shows that in the case of the substrate which was subjected to printing one time, the sensing resolution is high in a low strain region and stretchability is stably secured against a high strain until ε is 50%.

When the electrode is subjected to printing one time, the silver nanoparticles are impregnated to some extent into the substrate, but conductivity cannot be improved because impregnation for forming a conducting path is not achieved. However, when the electrode is subjected to printing five times, since the silver nanoparticles form the conducting path in the substrate, there is almost no change in resistance caused by the strain. This implies that the electrode which is subjected to printing one time is suitable for application to thin-film sensors and that the electrode which is subjected to printing five times is particularly very suitable as a stretchable electrode.

Although the preferred embodiments of the present invention have been disclosed for illustrative purposes, those skilled in the art will appreciate that various amendments and changes of the present invention are possible by additions, changes, deletion, or supplements of components, without departing from the spirit of the invention as disclosed in the accompanying claims, and that these are included in the scope of the present invention. For example, each component described as a single entity may be embodied in a distributed state, and components described as being distributed may be embodied in a combined form. The scope of the present invention is defined by the appended claims rather than the detailed description, and all changes or modifications derived from the meaning and scope of the claims and their equivalents are to be construed as being included within the scope of the present invention.

What is claimed is:

1. An electrode laminate comprising:
a flexible substrate including a recess unit; and
an electrode formed in the recess unit and including metal nanoparticles.

2. The electrode laminate of claim 1, wherein the recess unit is formed in a pattern on one side of the substrate.

3. The electrode laminate of claim 1, wherein the electrode further includes a polymer.

4. The electrode laminate of claim 3, wherein the polymer includes a material that is identical with a material of a substrate.

5. The electrode laminate of claim 1, wherein the recess unit is formed by impregnating the substrate with a print solution including the metal nanoparticles, from a surface of the substrate to an inside of the substrate.

6. The electrode laminate of claim 1, wherein the substrate includes one or more selected from the group consisting of an SBS block copolymer, an SEBS block copolymer, an SIS block copolymer, an SB block copolymer, an SMMA block copolymer, an SEO block copolymer, an SVP block copolymer, and polyurethane.

7. The electrode laminate of claim 1, wherein the metal nanoparticles include one or more metals selected from the group consisting of Ag, Au, Pt, Al, Cu, Pd, Li, and Zn.

8. The electrode laminate of claim 7, wherein the metal nanoparticles include silver.

9. An electrochemiluminescence element comprising:
a lower electrode including the electrode laminate according to claim 1;
an electrochemiluminescence gel formed on an electrode of the electrode laminate; and
an upper electrode formed on the electrochemiluminescence gel.

10. A method of manufacturing an electrode laminate, the method comprising:
(a) printing a conductive print ink including a metal precursor, an organic solvent, and a polymer on a flexible substrate to thus form a conductive print ink pattern impregnated in the substrate; and
(b) reducing the conductive print ink pattern to thus manufacture the electrode laminate.

11. The method of claim 10, wherein the printing the conductive print ink is performed using a nozzle or inkjet printer.

12. The method of claim 10, wherein the conductive print ink printed on the substrate swells and impregnates the substrate, from a surface of the substrate to an inside of the substrate.

13. The method of claim 10, wherein the printing the conductive print ink is performed multiple times over a same region of the substrate.

14. The method of claim 10, wherein the substrate includes one or more selected from the group consisting of an SBS block copolymer, an SEBS block copolymer, an SIS block copolymer, an SB block copolymer, an SMMA block copolymer, an SEO block copolymer, an SVP block copolymer, and polyurethane.

15. The method of claim 10, wherein metal ions of the metal precursor include one or more metal ions selected from the group consisting of Ag, Au, Pt, Al, Cu, Pd, Li, and Zn.

16. The method of claim 15, wherein the metal precursor includes one or more selected from the group consisting of CF₃COOAg, AgNO₃, AgCl, HAuCl₄, CuCl₂, PtCl₂, PtCl₄, CF₃COO₂Pd, CF₃CO₂Li, and Zn(CF₃COO)₂.

17. The method of claim 10, wherein the organic solvent includes one or more selected from the group consisting of acetone, butanone, methanol, ethanol, and butanol.

18. The method of claim 10, wherein the polymer includes one or more selected from the group consisting of an SBS block copolymer, an SEBS block copolymer, an SIS block copolymer, an SB block copolymer, an SMMA block copolymer, an SEO block copolymer, an SVP block copolymer, and polyurethane.

19. The method of claim 10, wherein the reducing the conductive print ink pattern printed on the substrate is performed by immersing the substrate that is subjected to printing in a reductant solution.

20. The method of claim 19, wherein a reductant includes one or more selected from the group consisting of hydrazine (N₂H₄), sodium borohydride (NaBH₄), formaldehyde (HCHO), and sodium hydroxide (NaOH).
